(19) United States
(12) Patent Application Publication
(10) Pub. No.: US 2010/0072579 A1
(43) Pub. Date: Mar. 25, 2010

(54) Through Substrate Conductors

(76) Inventors: Andreas Thies, Berlin (DE); Harry Hedler, Germering (DE)

Correspondence Address: SLATER & MATSIL, L.L.P., 17950 PRESTON ROAD, SUITE 1000, DALLAS, TX, 75252, US

(21) Appl. No.: 12/236,164

(22) Filed: Sep. 23, 2008

(51) Int. Cl. H01L 23/52; H01L 21/4763

(52) U.S. Cl. 257/621; 438/667; 257/E23.141; 257/E21.495

(57) ABSTRACT

Structures and methods of forming through substrate vias are disclosed. In one embodiment, the method includes forming a through substrate opening from a top surface of a substrate, the top surface including active devices, and filling the first through substrate opening with an ancillary material. A conductive capping layer is formed over the ancillary material to cap the first through substrate opening. The substrate is thinned from a back surface to expose a portion of the ancillary material, the back surface being opposite to the top surface. The ancillary material is removed from the first through substrate opening, and a conductor is formed by filling a conductive material into the through substrate opening.

### TECHNICAL FIELD

The present invention relates generally to semiconductor devices, and more particularly to through substrate conductors.

### BACKGROUND

One of the goals in the fabrication of electronic components is to minimize the size of various components. For example, it is desirable that hand held devices such as cellular telephones and personal digital assistants (PDAs) be as small as possible. To achieve this goal, the semiconductor circuits that are included within the devices should be as small as possible. One way of making these circuits smaller is to stack the chips that carry the circuits.

A number of ways of interconnecting the chips within the stack are known. For example, bond pads formed at the surface of each chip can be wire-bonded, either to a common substrate or to other chips in the stack. Another example is a so-called micro-bump 3D package, where each chip includes a number of micro-bumps that are routed to a circuit board, e.g., along an outer edge of the chip.

Yet another way of interconnecting chips within the stack is to use through-vias. Through-vias extend through the substrate thereby electrically interconnecting circuits on various chips. Through-via interconnections can provide advantages in terms of interconnect density compared to other technologies. However, introduction of such interconnects may introduce additional challenges.

The integration of chips in 3D brings forth new challenges that need to be addressed. One of the challenges arises due to reliable filling of vias with narrow diameters or large aspect ratios with a conducting material. This challenge increases dramatically as the diameter of the through substrate vias decreases. Hence, what is needed in the art are improved structures and methods of producing structures for 3D chip integration that overcome these challenges.

### SUMMARY OF THE INVENTION

These and other problems are generally solved or circumvented, and technical advantages are generally achieved, by preferred embodiments of the present invention which relate to semiconductor components with through substrate vias.

Embodiments of the invention include structures and methods of forming through substrate vias. In accordance with a preferred embodiment of the present invention, a method for forming through substrate vias comprises forming a through substrate opening from a top surface of a substrate, the top surface comprising active devices, filling the through substrate opening with an ancillary material, and capping the through substrate opening by forming a conductive capping layer over the ancillary material. The method further comprises thinning the substrate from a back surface to expose a portion of the ancillary material, the back surface being opposite to the top surface, removing the ancillary material from the through substrate opening, and forming a first conductor by filling a conductive material into the through substrate opening by starting from the conductive capping layer.

The foregoing has outlined rather broadly the features of an embodiment of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1, which includes FIGS. 1a and 1b, illustrates a through substrate via disposed through a semiconductor chip, wherein FIG. 1a illustrates a cross sectional view, and FIG. 1b illustrates a plane view, in accordance with an embodiment of the invention;

FIG. 2, which includes FIGS. 2a-2c, illustrates a semiconductor chip comprising through substrate vias, in accordance with an embodiment of the invention;

FIG. 3, which includes FIGS. 3a-3e, illustrates a magnified plane view of through substrate vias looking through a cross section of the semiconductor chip, in accordance with an embodiment of the invention;

FIG. 4, which includes FIGS. 4a-4m, illustrates fabrication of a through substrate via in various stages of processing, in accordance with an embodiment of the invention;

FIG. 5 illustrates a flow chart of the process steps used in the fabrication of a stacked chip as illustrated in FIG. 4;

FIG. 6, which includes FIGS. 6a-6c, illustrates fabrication of a through substrate via in various stages of processing, in accordance with an embodiment of the invention;

FIG. 7 illustrates a flow chart of the process steps used in the fabrication of a stacked chip as illustrated in FIG. 6;

FIG. 8, which includes FIGS. 8a-8c, illustrates fabrication of a through substrate via in various stages of processing, in accordance with an embodiment of the invention;

FIG. 9 illustrates a flow chart of the process steps used in the fabrication of a stacked chip as illustrated in FIG. 8; and

FIG. 10, which includes FIGS. 10a-10e, illustrates fabrication of a stacked chip comprising through substrate vias in various stages of processing, in accordance with an embodiment of the invention;

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely through substrate vias in semiconductor components. The invention may also be applied, however, to other semiconductor components comprising, for example, multiple chips stacked together using other types of interconnects. One of ordinary skill in the art will be able to recognize further examples as well.

Embodiments of the present invention utilize through substrate vias to create 3D chip packages. Stacking chips on top of one another provides a means to achieve density, increased functionality and/or additional performance. One way to realize the full benefits of chip stacking is to connect the chips using deep, or through substrate, vias. These vias extend from the active circuitry at one face of the chip to a bottom surface of the chip.

One of the key problems associated with stacking such devices arises from the complexity of the fabrication process of the through substrate via. In particular, the filling of the through substrate via introduces process complexity that increases process costs as well as tending to introduce defects that may significantly impact yield. Traditional processes include either via first or via last. In via first processes, the via and the conductive fill are formed during or before completion of back end of the line processes. However, this imposes severe restrictions on the back end of the line processes. Similarly, in the via last approach, the via opening and the via fill are performed after back end of the line processing. However, as the via opening is formed from the back side, aligning the via correctly is a major challenge. Similarly, stopping the via on a suitable metal level is also very difficult.

In various embodiments of the invention, these limitations are overcome by forming the via opening from the front side, before completion of the back end of the line processing and back end metallization. Further, in various embodiments described in the invention, the via opening is filled with a conductive fill material after the back end metallization thereby overcoming the problems with back end metal restrictions.

In various embodiments, the invention reduces the complexity of the through substrate via formation processes. The complexity of the through substrate via formation process arises from a number of requirements that include a need for a conformal and uniform seed layer and barrier layer. For example, non-uniformities in the seed layer can result in different growth rates along the depth of the through substrate via, effectively forming voids within. Similarly, a conformal barrier layer is required for preventing out-diffusion of the conductive atoms from within the through substrate via into the substrate.

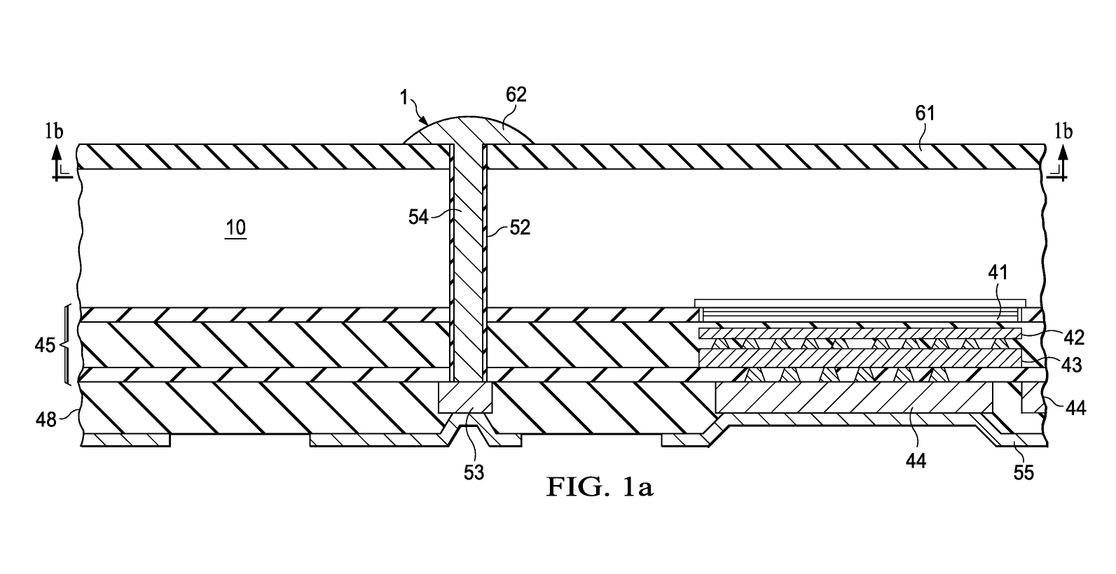

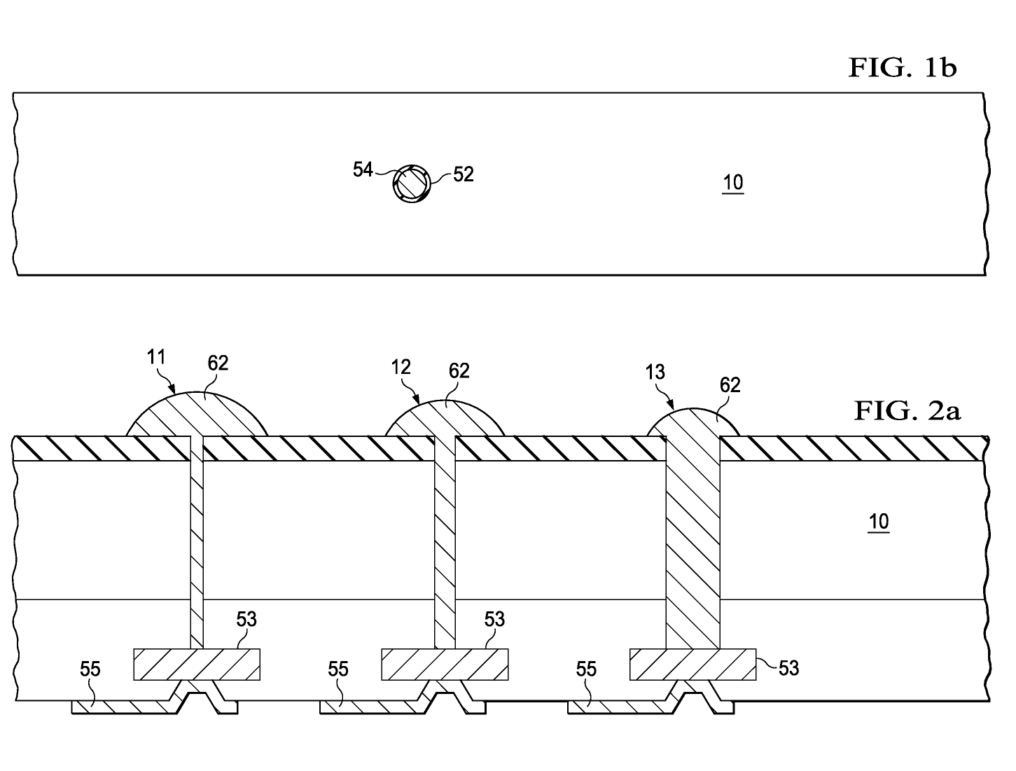

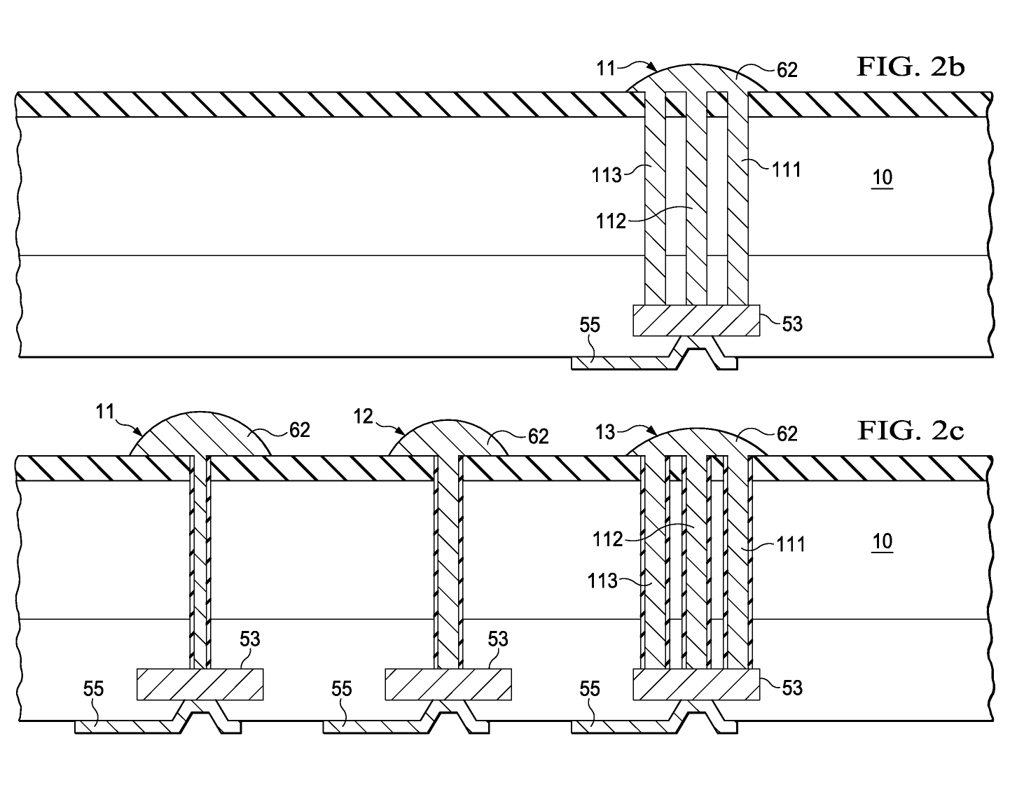

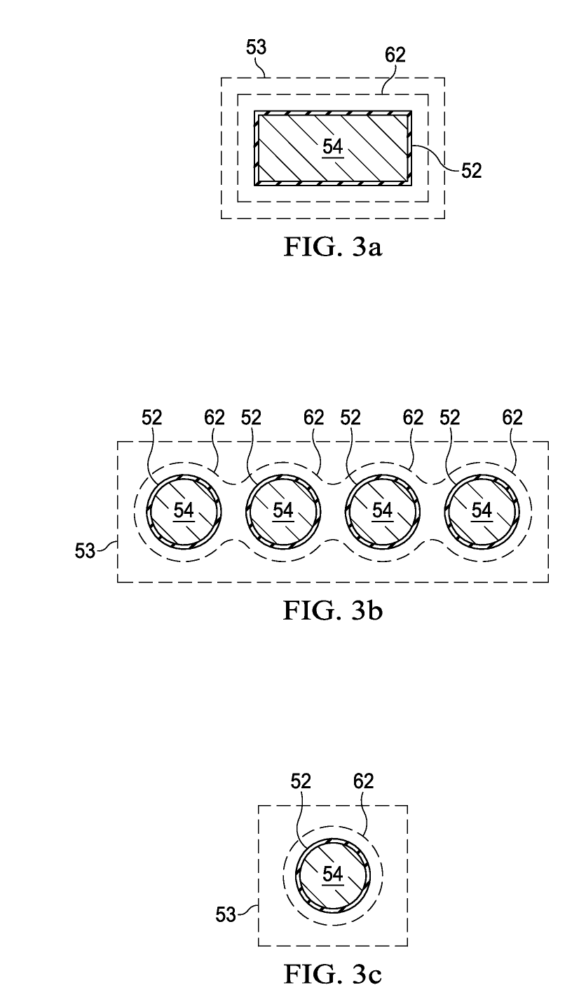

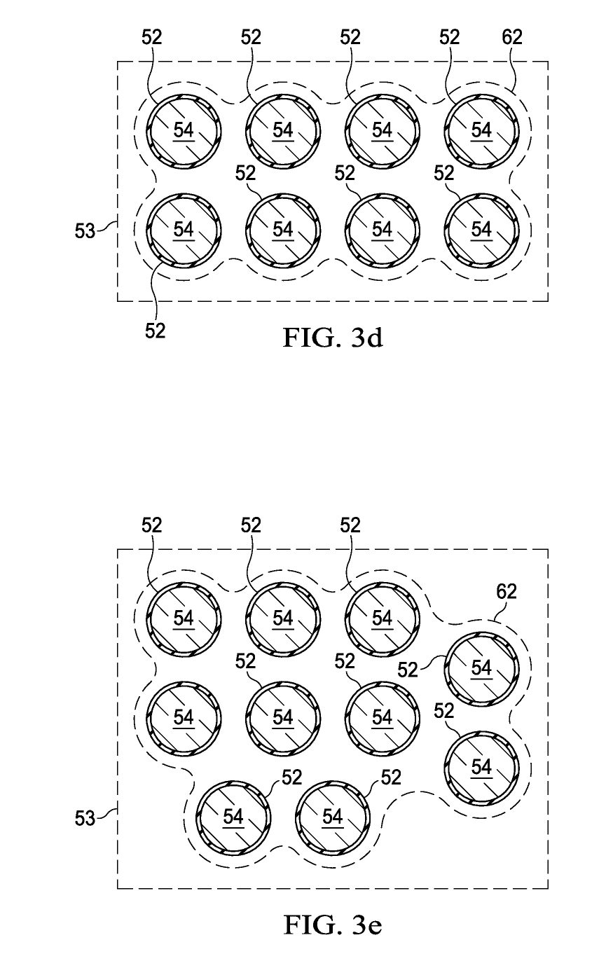

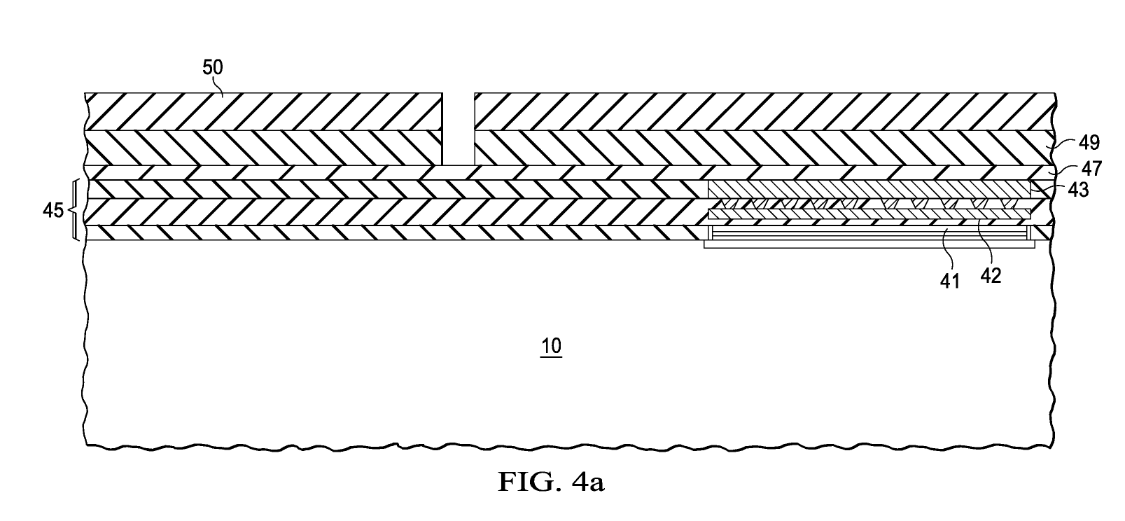

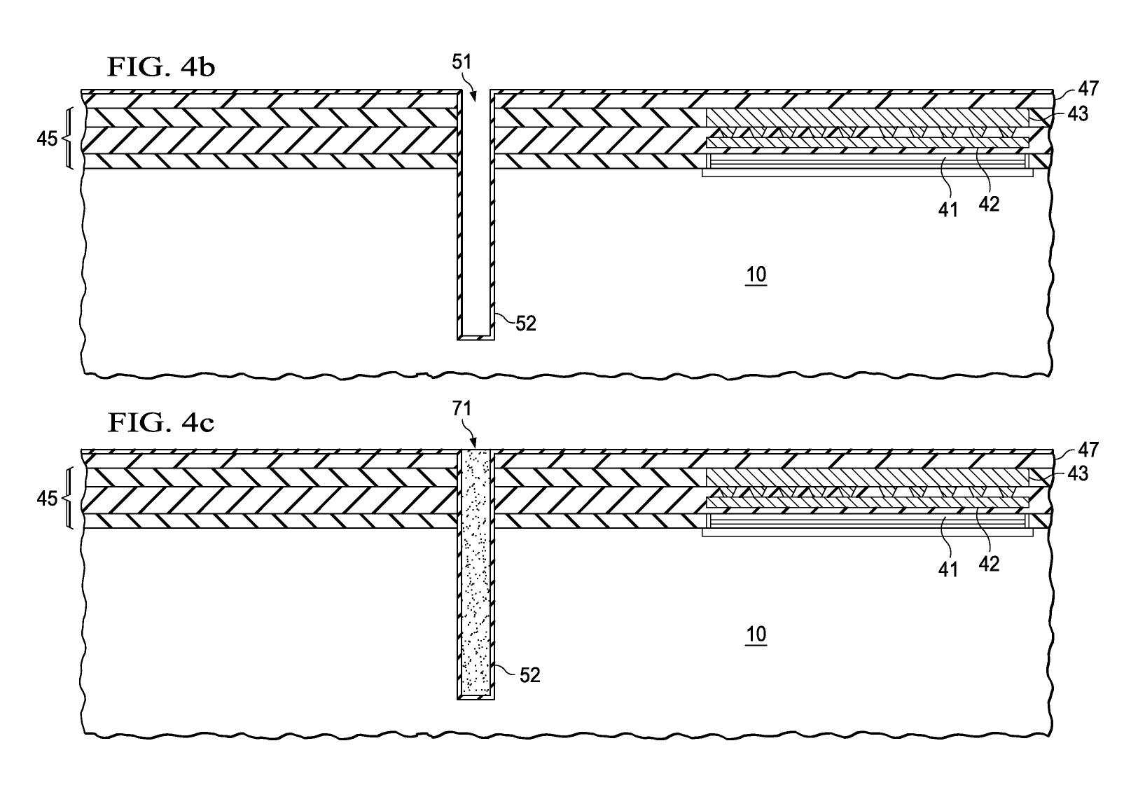

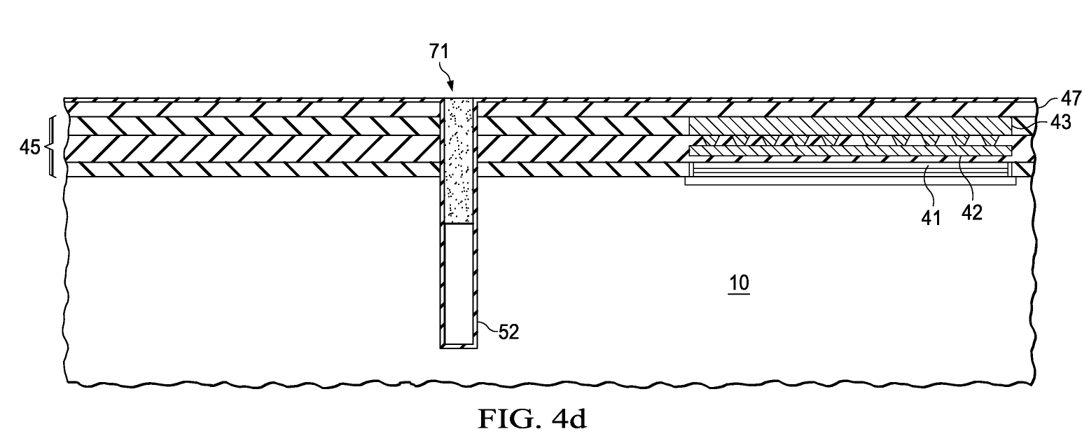

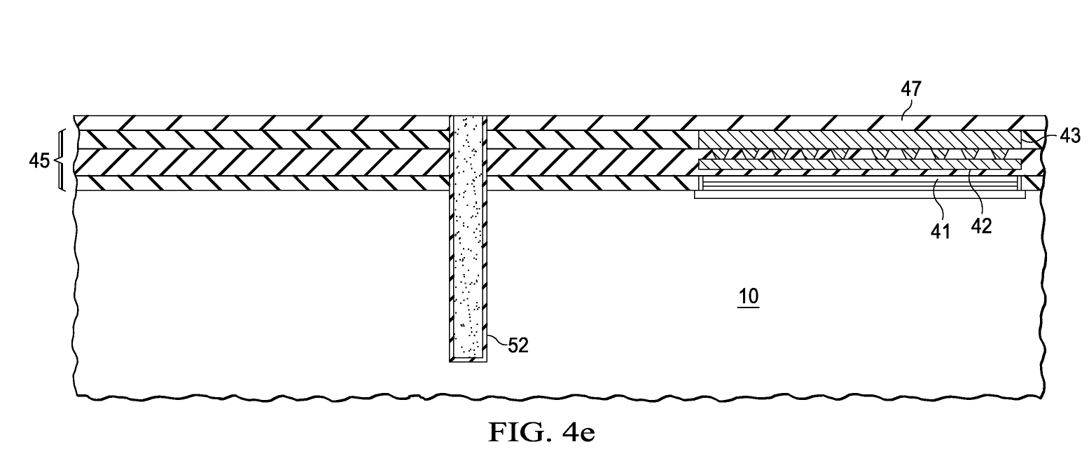

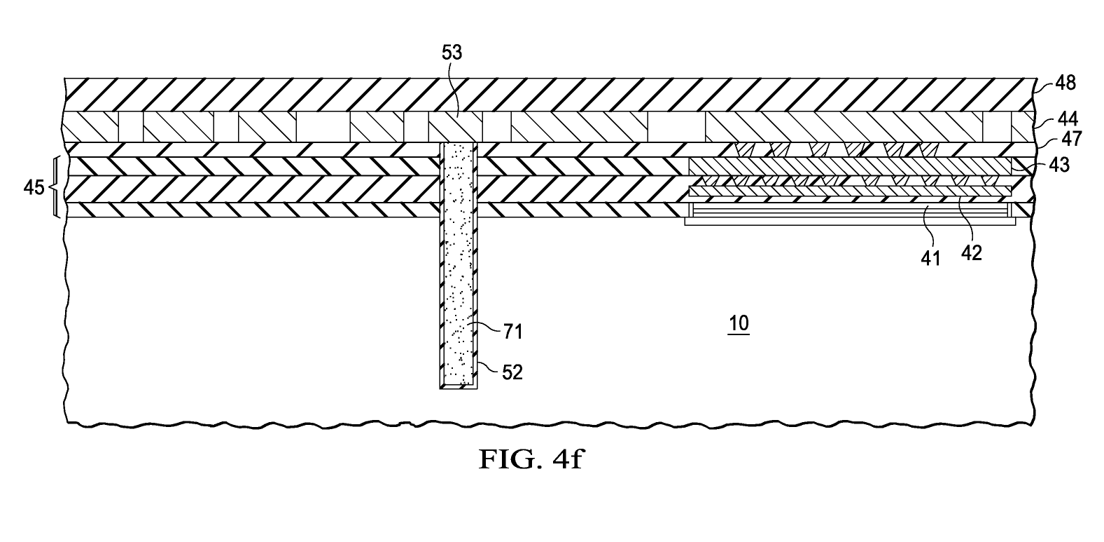

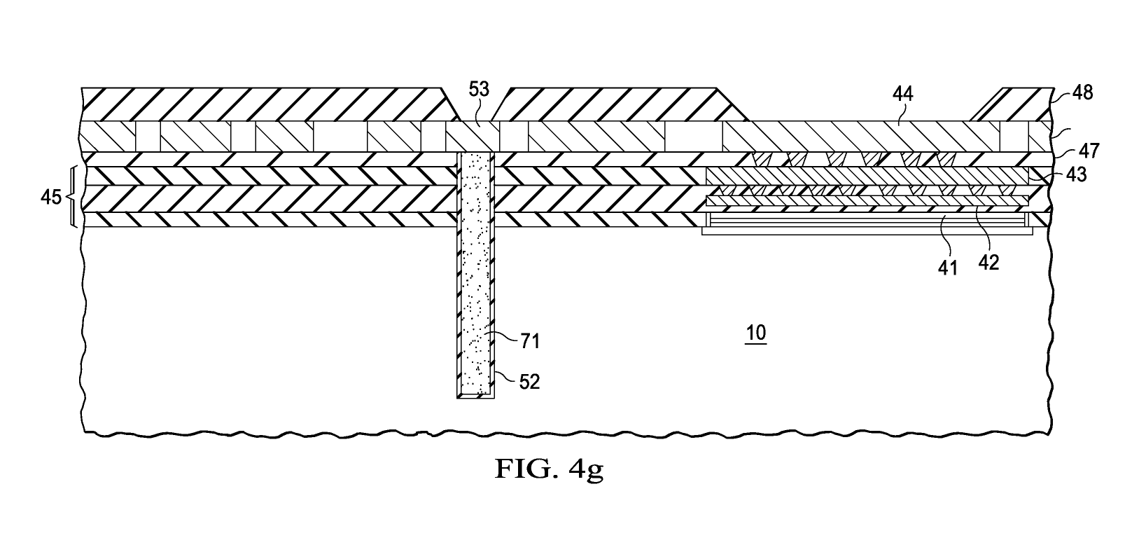

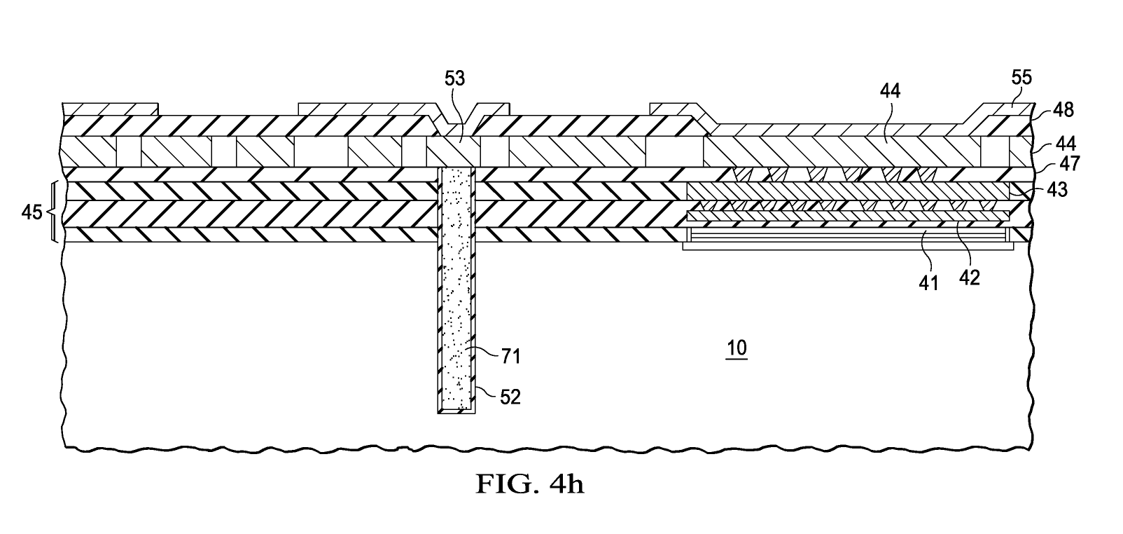

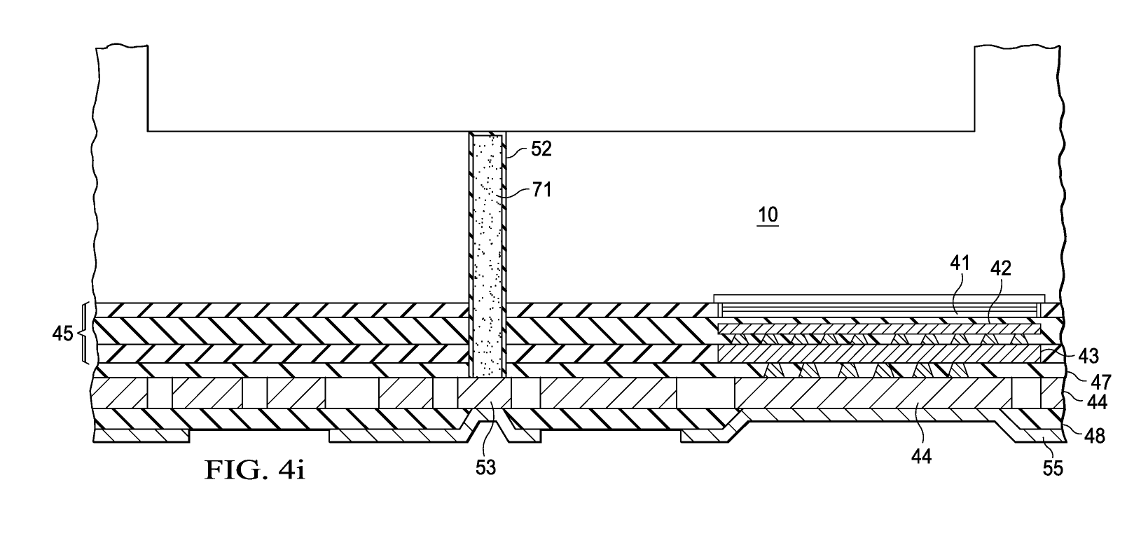

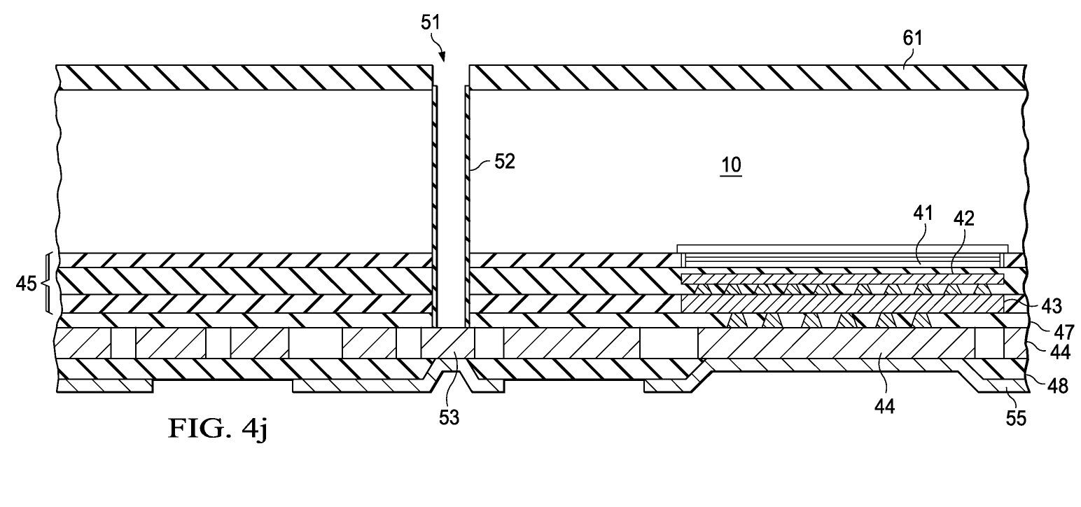

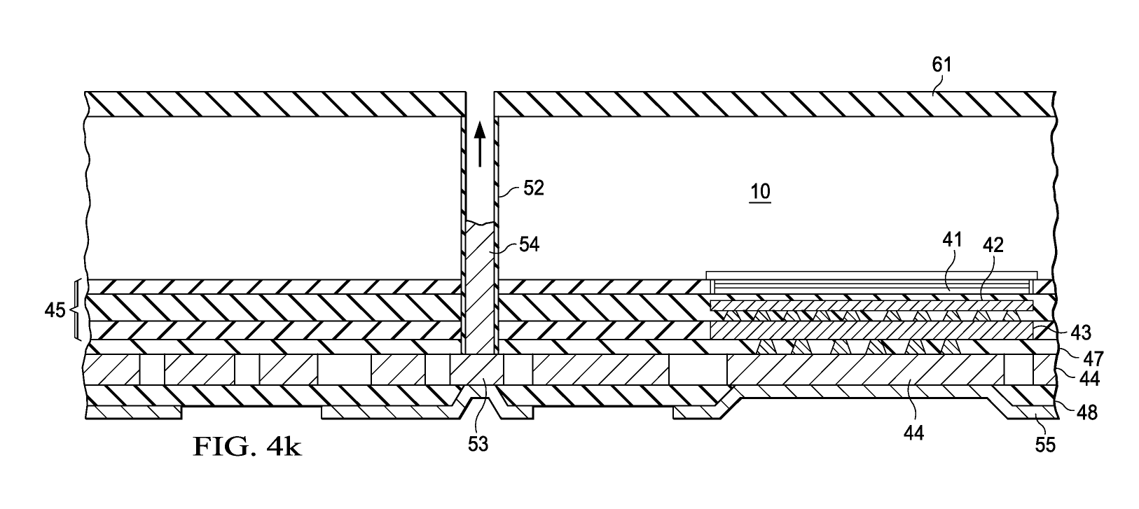

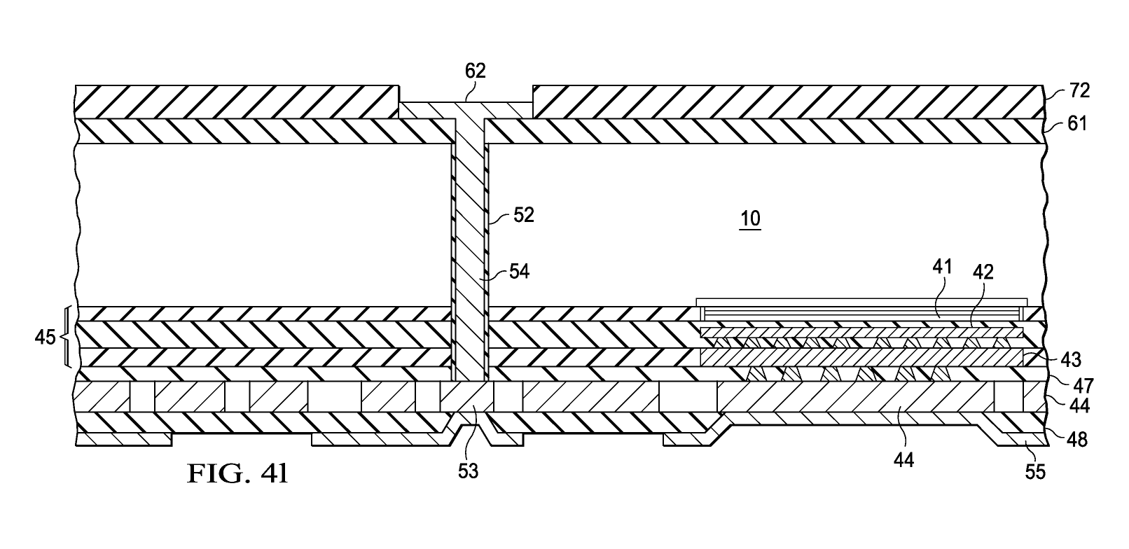

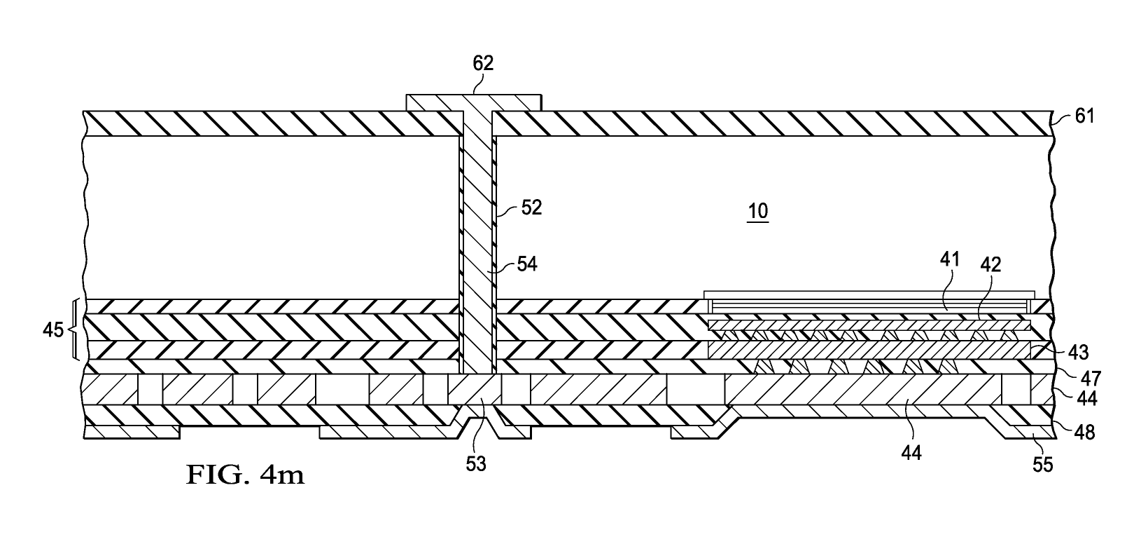

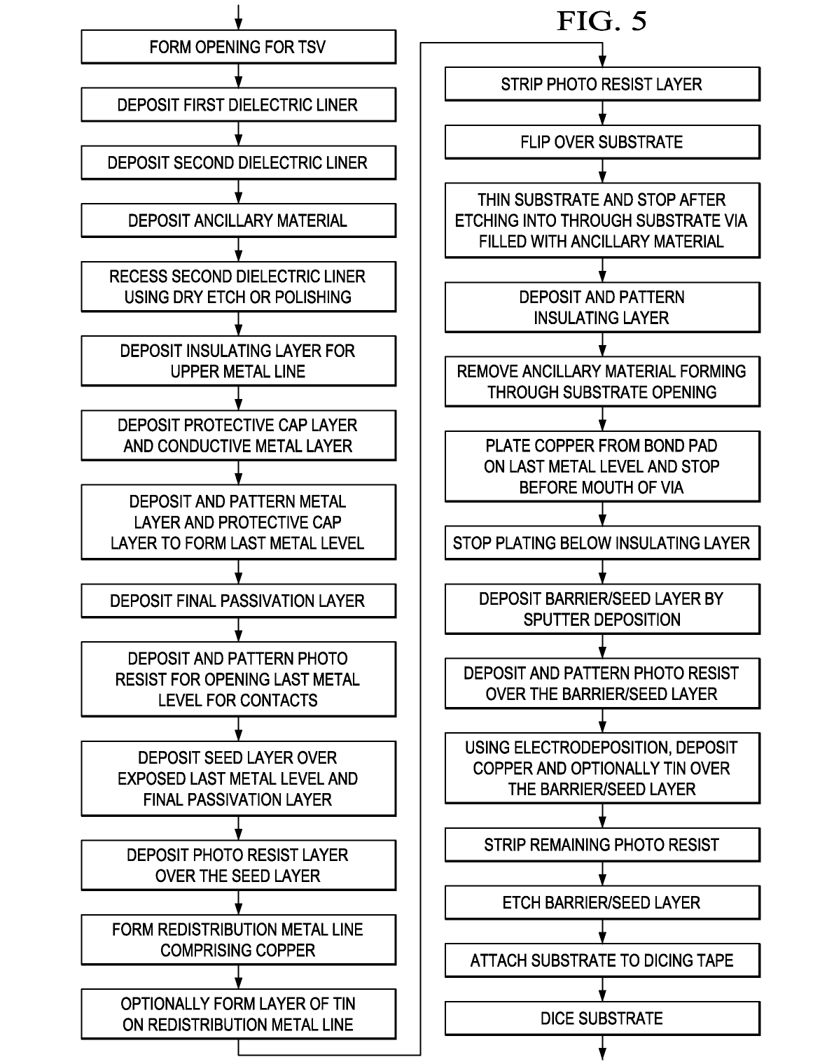

A structural embodiment of the invention illustrating a through substrate via is described in FIG. 1. Further structural embodiments are described in FIGS. 2 and 3. Embodiments of methods of forming through substrate vias are further described using FIGS. 4, 6, 8, and 10, along with the flow charts of FIGS. 5, 7, and 9.

FIG. 1, which includes FIGS. 1a and 1b, illustrates an embodiment comprising a through substrate via 1. FIG. 1a illustrates a cross sectional view, whereas FIG. 1b illustrates a plane view of the through substrate via 1.

Referring to FIG. 1a, the through substrate via 1 is disposed in the substrate 10. The substrate 10 comprises active devices disposed adjacent the top surface. Metallization levels connecting the active devices are disposed above the substrate 10. In the embodiment illustrated, only three metal levels are illustrated, although in other embodiments more or fewer metal levels may be present. For example, a first metal level 42 (M₀), a second metal level 43 (M₁), and the last metal level 44 (ML) are illustrated above the gate level 41. The metal levels are formed in a first insulating layer 45. Although illustrated as a single layer, the first insulating layer 45 comprises multiple layers. In various embodiments, each metal level is formed after forming a portion of the first insulating layer 44. In various embodiments, the first insulating layer 45 comprises multiple layers comprising different dielectric materials.

A front side bond pad 53 is disposed over the last metal level 44. A passivation layer 48 is disposed over the first insulating layer 45. The passivation layer 48 exposes the front side bond pad 53. A redistribution line 55 is disposed over the front side bond pad 53.

The through substrate via 1 extends from the front side bond pad 53 through the substrate 10 to the back side bond pad 62. A back side insulating layer 61 is disposed under the substrate 10. The back side bond pad 62 extends between the back side insulating layer 61. In various embodiments, the through substrate via 1 comprises a high aspect ratio (ratio of height to diameter of the through substrate via 1). The through substrate via 1 comprises an aspect ratio of about 15 to about 150, and about 100 in one embodiment.

FIG. 1b illustrates a plane view of the through substrate via along a cut place parallel to the surface of the substrate 10. As illustrated in FIG. 1b, the through substrate via 1 comprises an inner layer comprising a conductive fill material 54 and an outer dielectric liner 52 insulating the conductive fill material 54 from the substrate 10. The dielectric liner 52 comprises a single or multiple dielectric layers. In one embodiment, the dielectric liner 52 comprises an oxide liner abutting the substrate 10, and a nitride liner disposed on the oxide liner. In such an embodiment, the conductive fill material 54 is disposed on the nitride liner. The conductive fill material 54 comprises any suitable conductive material. In one embodiment, the conductive fill material 54 comprises copper. The through substrate via 1 does not comprise further liners disposed over the dielectric liner 52. For example, in various embodiments, conductive barrier layers and conductive seed layers are not disposed on the dielectric liner 52.

FIG. 2, which includes FIGS. 2a-2c, illustrates cross sectional views of a semiconductor chip comprising through substrate vias. In various embodiments, as described further below in detail, the simple one-dimensional fill process minimizes process complexity of the fill process. Hence, as illustrated in FIG. 2, different configurations and shapes of through substrate vias can be formed in various embodiments.

FIG. 2a illustrates an embodiment illustrating a first through substrate via 11, a second through substrate via 12, and a third through substrate via 13 formed in a substrate 10. The first, the second and the third through substrate vias 11, 12, and 13 comprise different sizes or widths. The width of the first through substrate via 11 is less than the width of the second through substrate via 12, and the width of the second through substrate via 12 is less than the width of the third through substrate via 13. In various embodiments, through substrate vias of multiple widths are formed simultaneously due to the improved process as will be described below.

FIG. 2b illustrates a first through substrate via 11 comprising a first vertical pillar 111, a second vertical pillar 112, and a third vertical pillar 113. Although not shown, in various embodiments more than three vertical pillars may be formed. In various embodiments, the multiple pillars are arranged in parallel forming a bundle. The first, the second, and the third vertical pillars 111, 112, and 113 are coupled to a common front side bond pad 53 and back side bond pad 62.

FIG. 2c illustrates an embodiment illustrating a first through substrate via 11, a second through substrate via 12, and a third through substrate via 13 formed in a substrate 10. As described with respect to FIG. 2a, the first, the second, and the third through substrate vias 11, 12, and 13 comprise different sizes or widths. As described with respect to FIG. 2b, the third through substrate via 11 comprises multiple vertical pillars coupled to a front side bond pad 53 and a back side bond pad 62. FIG. 2c illustrates three pillars, a first vertical pillar 111, a second vertical pillar 112 and a third vertical pillar 113, although in other embodiments more than three pillars are formed. In various embodiments, the first, the second, and the third through substrate vias 11, 12, and 13 comprise large aspect ratios. In one embodiment, the first, the second, and the third through substrate vias 11, 12, and 13 comprise aspect ratios of about 10 to about 100.

FIG. 3, which includes FIGS. 3a-3e, illustrates plane views of the through substrate vias formed in various embodiments.

FIG. 3 illustrates plane views of through substrate vias 1 formed over the front side bond pad 53 (illustrated as dashed lines). In various embodiments, the through substrate vias 1 comprise different shapes and are arranged in different configurations. FIG. 3 also illustrates the back side bond pad 62 (illustrated as dashed lines) formed over the through substrate vias 1 in an embodiment wherein the back side bond pad 62 is formed together with the through substrate vias 1 in a common electro deposition process. FIGS. 3a and 3c illustrate a single through substrate via 1, whereas FIGS. 3b, 3d, and 3e illustrate a bundle of through substrate vias 15. The bundle of through substrate vias 15 is arranged in different shapes as illustrated in FIGS. 3b, 3d, and 3e.

FIG. 4, which includes FIGS. 4a-4m, along with the flow chart of FIG. 5, illustrates an embodiment of the invention describing steps during fabrication of a through substrate via.

Referring to FIG. 4a and as illustrated in the flow chart of FIG. 5, device regions are formed near a top surface of a first substrate 10 during front end processing. The first substrate 10 is typically a semiconductor wafer. The device regions or active circuitry can include transistors, resistors, capacitors, inductors or other components used to form integrated circuits. For example, active areas that include transistors (e.g., CMOS transistors) are formed separated from one another by isolation regions, e.g., shallow trench isolations.

Next, a metallization layer is formed over the device regions to electrically contact and interconnect the device regions. The metallization and active circuitry together form a completed functional integrated circuit. In other words, the electrical functions of the chip can be performed by the interconnected active circuitry. In logic devices, the metallization may include many layers, e.g., nine or more, of copper. In memory devices, such as DRAMs, the number of metal levels may be less and may be aluminum.

The components formed during the front-end processing are interconnected by back end of line (BEOL) processing. During this process, contacts are made to the semiconductor body and interconnected using metal lines and vias. As discussed above, modern integrated circuits incorporate many layers of vertically stacked metal lines and vias (multilevel metallization) that interconnect the various components in the chip. In FIG. 4a, only two levels of metal (first metal level 42 (M₀) and second metal level 43 (M₁)) are illustrated above the gate level 41. The metal levels are formed in an insulating layer 45 after forming the contact plugs contacting the active devices. Although illustrated as a single layer, the insulating layer 45 comprises multiple layers. In various embodiments, each metal level is formed after forming a portion of the insulating layer 45. In various embodiments, the insulating layer 45 comprises multiple layers comprising different dielectric materials. Further, in FIG. 4, the metallization layers are illustrated only in a small portion above the substrate 10 to illustrate the placement of these layers.

The insulating layer 45 comprises insulating materials typically used in semiconductor manufacturing for inter-level dielectric (ILD) layers, such as SiO₂, tetra ethyl oxysilane (TEOS), fluorinated TEOS (FTEOS), doped glass (BPSG, PSG, BSG), organo silicate glass (OSG), fluorinated silicate glass (FSG), spin-on glass (SOG), SiN, SiON, or low k insulating materials, e.g., having a dielectric constant of about 4 or less, or combinations or multiple layers thereof, as examples, although alternatively, the insulating layer 45 may comprise other materials. The ILD layers may also comprise dense SiCOH or a porous dielectric having a k value of about 3 or lower, as examples. The ILD layers may also comprise an ultra-low k (ULK) material having a k value of about 2.3 or lower, for example. The ILD layers may comprise a thickness of about 500 nm or less, for example, although alternatively, the ILD layers may comprise other dimensions.

A second insulating layer 47 is deposited over the first insulating layer 45. The second insulating layer 47 comprises an oxide layer in one embodiment. A hard mask layer 49 is deposited over the second insulating layer 47. The hard mask layer 49 protects the top surface of the second insulating layer 47 during the through trench etch. The hard mask layer 49 is selected based on the selectivity of the through trench etch process. Through trench etch processes using a high density plasma with a fluorine chemistry typically utilize a SiO₂ hard mask layer 49. The hard mask layer 49 comprises a single layer in one embodiment. In other embodiments, a bi-layer or tri-layer hard mask layer can be used. A photo resist layer 50 is deposited over the hard mask layer 49. Using photo lithography the photo resist layer 50 is exposed, developed, and patterned. Using the patterned photo resist layer 50, the hard mask layer 49 is patterned.

Referring to FIG. 4b, a through substrate opening 51 is formed. Although only one through substrate opening 51 is illustrated, a chip may comprise more than one through substrate opening 51.

The through substrate opening 51 is formed using a resist only etch, a Bosch process, or by depositing a hard mask layer and etching the substrate 10 using a vertical reactive ion etch. Although the Bosch process results in rough sidewalls, in various embodiments, a rough sidewall does not introduce any challenge for the subsequent fill processes. This is because the invention does not require growing from the sidewalls of the opening 51. Hence, the surface roughness (which is very important if the growth front starts from the vertical sidewalls) is not a significant control parameter.

Referring again to FIG. 4b, a dielectric liner 52 is deposited over the through substrate opening 51. The dielectric liner 52 is deposited over the sidewalls and bottom surface of the through substrate opening 51. The dielectric liner 52 electrically isolates the conductive material in the through substrate via 1 from active devices on the first substrate 10. The dielectric liner 52 is deposited conformally over the exposed surfaces of the through substrate opening 51. The dielectric liner 52 may be deposited by a suitable low temperature process such as plasma enhanced CVD and/or organic vapor phase deposition. In some embodiments, the dielectric liner 52 is anisotropically etched forming a sidewall on the through substrate opening 51. In one embodiment, the dielectric liner 52 is removed from the bottom of the through substrate opening 51 after thinning of the first substrate 10. In one embodiment the dielectric liner 52 comprises an oxide layer and a nitride layer disposed on the oxide layer.

Referring to FIG. 4c, an ancillary material 71 is filled into the through substrate opening 51 covering the dielectric liner 52. The ancillary material 71 is overfilled to form a smooth surface. The ancillary material 71 comprises a material that can be selectively removed with respect to the dielectric liner 52. In one embodiment, the ancillary material 71 comprises spin-on glass materials, spin-on oxides, and spin-on nitride. In various embodiments, the ancillary material 71 is deposited using a spin-on process. The ancillary material 71 can be deposited in multiple steps in some embodiments. In one embodiment, the ancillary material 71 is deposited by depositing a first layer followed by a curing step, which is again followed by a second deposition and curing step to form a second layer. The cycle is followed to form the ancillary material 71 comprising multiple layers. In yet another embodiment, the ancillary material 71 is partially deposited as illustrated in FIG. 4d. The partial fill reduces the difficulty of removing the ancillary material 71 from the back surface as detailed in subsequent steps.

As illustrated in FIG. 4e, the dielectric liner 52 is recessed and removed from over the substrate 10. In various embodiments, the dielectric liner 52 is removed using a polishing process such as chemical mechanical polishing. In some embodiments, a wet etch is used to remove the dielectric liner 52. The wet etch chemistry is selected to remove the dielectric liner 52 without removing the ancillary material 71. In some embodiments, the dielectric liner 52 is not removed, especially in embodiments when the dielectric liner 52 comprises a nitride material.

Referring to FIG. 4f, a last metal level 44 (ML) is formed over the substrate 10. The last metal level 44 comprises the front side bond pad 53 disposed over the through substrate via 1. In forming the last metal level 44, a protective cap liner and a conductive metal layer are deposited over the through substrate opening 51. The last metal level 44 is formed by structuring the protective cap liner and the conductive metal layer, for example using a subtractive etch process.

In various embodiments, the protective cap liner comprises TiN or TaN. In some embodiments, the protective cap liner comprises a metal (e.g., Ru, Hf, Ti, Ta, Ti, La, V, Nb, Pr, Dy, Sr, Gd, Mo); metal alloys (e.g., TiW); nitrides (e.g., TiN, TaN, HfN, TaSiN, TiWN, NbN, MoN, TiAlN, MoSiN, HfSiN, TiSiN, or combinations of these); carbo-nitrides (e.g., TiCN, NbCN, HfCN, TaCN); or silicides (e.g., TiSi₂, WSi₂).

In one embodiment, the protective cap liner is selected to have sufficient etch selectivity to the ancillary material 71 so that it is not removed during etching of the ancillary material 71. In such an embodiment, the protective cap liner also forms the seed layer for subsequent deposition processes. If the protective cap liner is removed during the etching of the ancillary material 71, the conductive metal layer disposed above the protective cap liner forms the seed layer.

In one embodiment, the conductive metal layer is aluminum, although other suitable metal can be deposited. In other embodiments, the conductive metal layer comprises copper or other metals. The conductive metal layer and the protective cap layer are etched to form the last metal level 44.

In various embodiments, subsequent processing continues as in regular semiconductor processing to finish up metallization and contact layers. In one embodiment, as illustrated in FIG. 4f, a passivation layer 48 is deposited over the last metal level 44. The passivation layer 48 comprises oxide in one embodiment, although in other embodiments other suitable materials are used. The passivation layer 48 can include more than one layer of material, such as silicon oxide, silicon nitride or silicon oxynitride or polyimide, as just a few examples. Referring to FIG. 4g, the passivation layer 48 is patterned to expose selected regions of the last metal level 44. The exposed regions of the last metal level 44 include openings to form bond pads and/or contacts.

In various embodiments, different schemes for contacting the active circuitry and through substrate via (to be formed) with various components are used. In one embodiment, redistribution lines are formed over the metallization and contact layers. Referring to FIG. 4h, a redistribution line 55 is formed over the passivation layer 48. A copper seed layer is first deposited over the passivation layer 48 followed by the deposition of a photo resist. Using a photo lithography process, the photo resist is patterned to expose a part of the copper seed layer. The redistribution line 55 is formed by a subsequent electroplating process that selectively deposits over the exposed copper seed layer. The remaining patterned photo resist is removed followed by the removal of the seed layer underneath the patterned photo resist layer forming redistribution line 55 isolated by the passivation layer 48.

Next, as illustrated in FIG. 4i, the substrate 10 is thinned in the central region. In various embodiments, the thickness of the substrate 10 after the thinning process is about 30 um to about 150 um, and typically about 60 um. A region is left around the edge forming a ring of semiconductor around the substrate 10. The ring of semiconductor provides stability and prevents damage to the substrate 10 during the aggressive thinning process. In various embodiments, other thinning processes may be used such as complete wafer thinning after attaching the substrate 10 to a conductive support.

Next as illustrated in FIG. 4j, the ancillary material 71 is removed forming the through substrate opening 51. A back side insulating layer 61 is deposited over the back surface of the thinned substrate 10. In one embodiment, the back side insulating layer 61 comprises an oxide and is deposited using a chemical vapor deposition process. The back side insulating layer 61 is patterned to expose the ancillary material 71. The ancillary material 71 is etched using a wet etch process. Due to the high selectivity of the wet etch to the ancillary material 71 relative to the dielectric liner 52 and the protective cap layer of the front side bond pad 53, only the ancillary material 71 is removed during the etch.

Referring to FIG. 4k, a conductive fill material 54 is deposited into the through substrate opening 51. In various embodiments, the conductive fill material 54 comprises a material whose deposition is enhanced, for example, by the underlying protective cap liner. In one embodiment, the conductive fill material 54 precipitates from an aqueous solution. Examples of such conductive fill material 54 include nickel, gold, tin, silver, and their alloys. In other embodiments, alloys, for example, nickel molybdenum (NiMo) alloys, iron phosphide (FeP) alloys, and nickel phosphide (NiP) alloys, may be deposited by a galvanic deposition process. In yet another embodiment, the conductive fill material 54 comprises aluminum. In various embodiments, the conductive fill material 54 is deposited using an electroplating process, or an electroless plating process such as plating in the presence of a catalyst. In one embodiment of an electroless plating process, the underlying protective liner acts as the necessary catalyst.

In various embodiments, the conductive fill material 54 is deposited using an electroplating process. The conductive fill material 54 is electrodeposited onto the protective cap layer of the front side bond pad 53. If the protective cap layer is removed during the removal of the ancillary material 71, the electroplating starts from the conductive metal layer of the front side bond pad 53.

The growth front of the electroplating process is essentially a one dimensional process as the plating proceeds from the front side bond pad 53. The plating does not proceed inward from the sidewall of the through substrate opening 51 as in typical via fill processes. This is because the through substrate opening 51 is not lined with a conductive material that is required to produce the current density for the electroplating process. In a conventional process, the growth front is three-dimensional due to the conductive material lining the sidewalls of the opening. The conductive liner is an essential requirement of a conventional process. Filling openings with large aspect ratios is challenging if not impossible when the growth front is three-dimensional as in a conventional process. This is because in a three dimensional growth process, the growth front from the sidewalls merge before the opening is filled up, thus forming voids within the through substrate opening. Further, the current density is less at the bottom of an opening than on the sidewalls (due to resistance of the seed layer). This results in a slower growth on the bottom surface than the sidewalls, magnifying the problem.

As next illustrated in FIG. 41, the electroplating process is stopped as the through substrate via is filled. No excess overfill layer is formed on the filled through substrate via. A photo resist layer 72 is deposited and patterned to open areas for forming back side contacts. A conductive material is deposited between the patterned photo resist layer 72, forming back side bond pads 62. In one embodiment, the back side bond pads 62 are electroplated onto the conductive liner, the conductive liner being deposited before depositing the photo resist layer 72. The photo resist layer 72 is removed as illustrated in FIG. 4m followed by a seed layer etch.

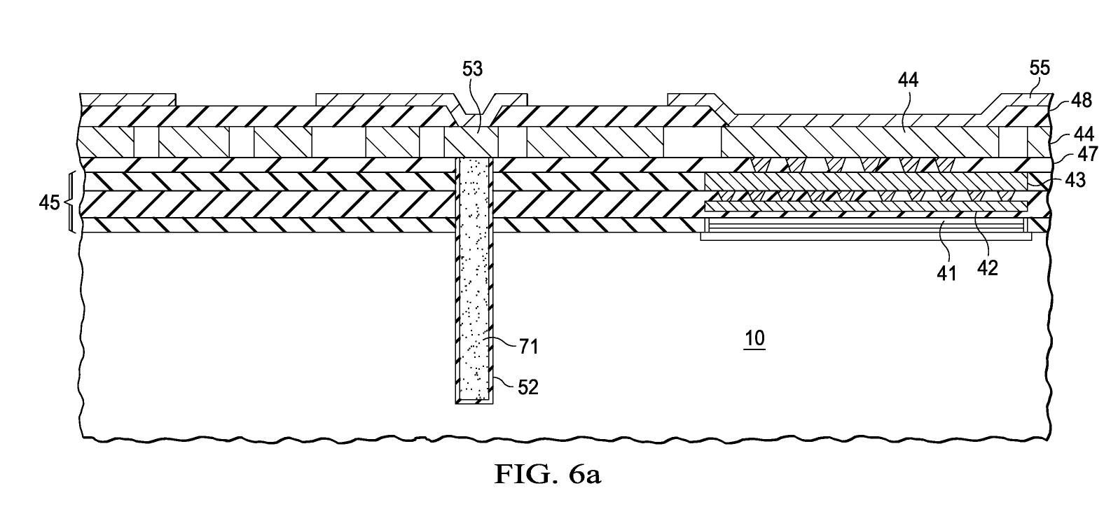

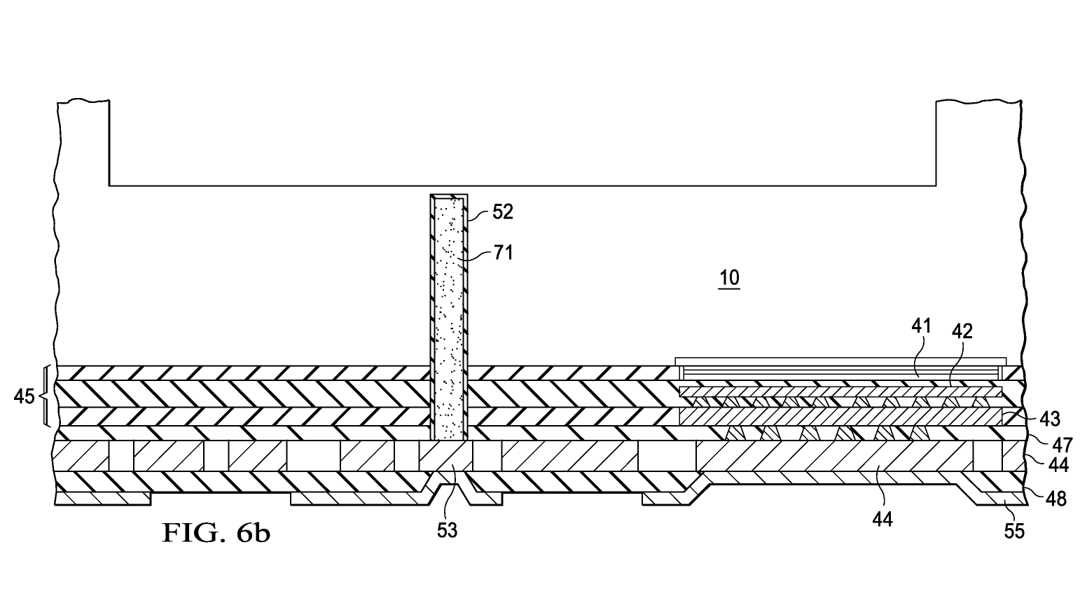

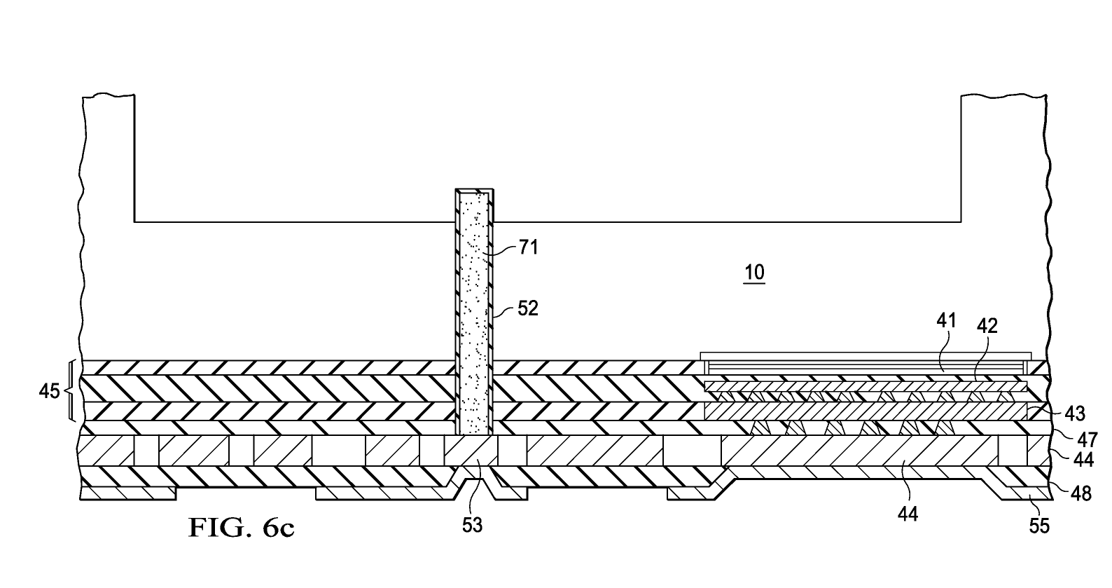

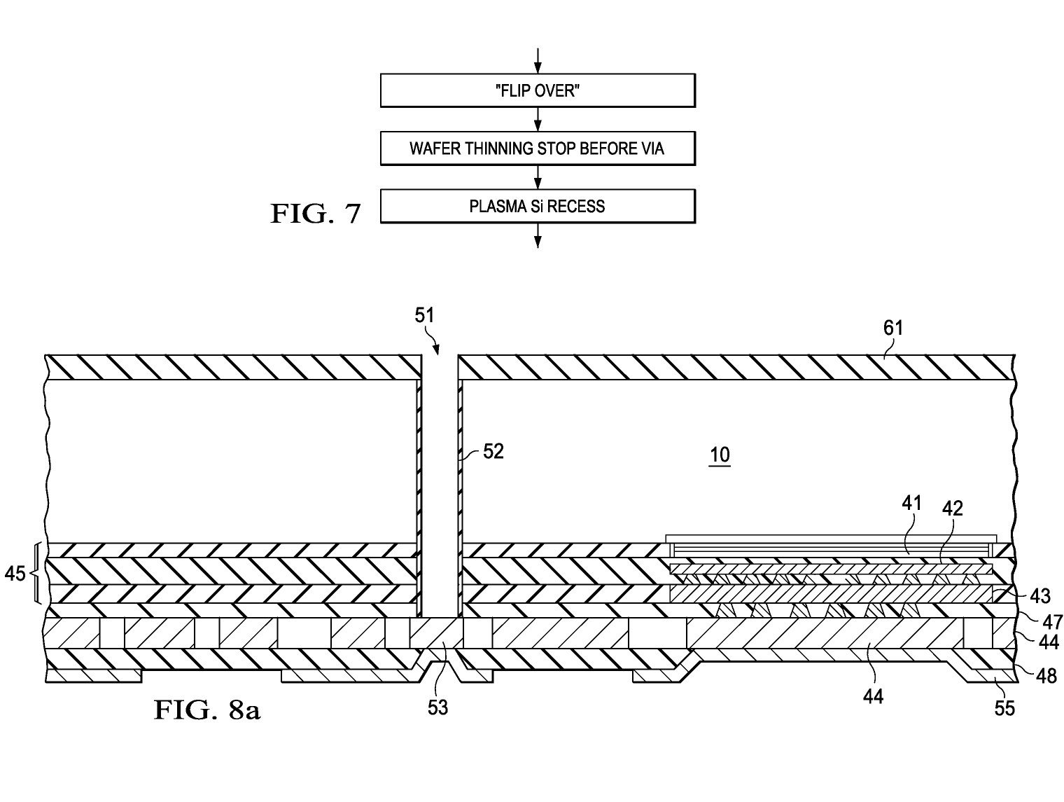

FIG. 6, which includes FIGS. 6a-6c, along with the flow chart of FIG. 7, illustrates an embodiment of the invention describing steps during fabrication of a through substrate via.

As illustrated in FIG. 6a, the embodiment proceeds similar to the prior embodiment as described with respect to FIGS. 4a-4h. However, the thinning process is performed in multiple steps unlike the prior embodiment. As illustrated in FIG. 6b, a first mechanical thinning is performed that stops above the through substrate via. Hence, the ancillary material 71 is not exposed. After the mechanical thinning, a plasma process is used to etch additional layers of the substrate 10. The plasma process is preferable to avoid damaging the through substrate opening 51. In one embodiment, the plasma process is a reactive ion etch process. In one embodiment, an anisotropic etch chemistry comprising HBr, Cl₂, or Cl₂HBr/O₂ is used. Subsequent processing proceeds as described in the prior embodiment.

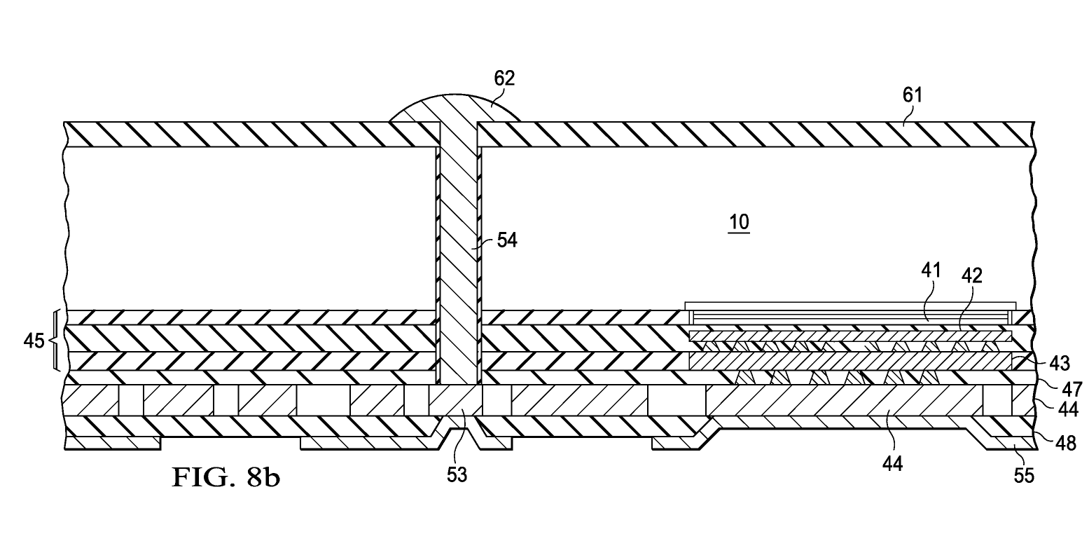

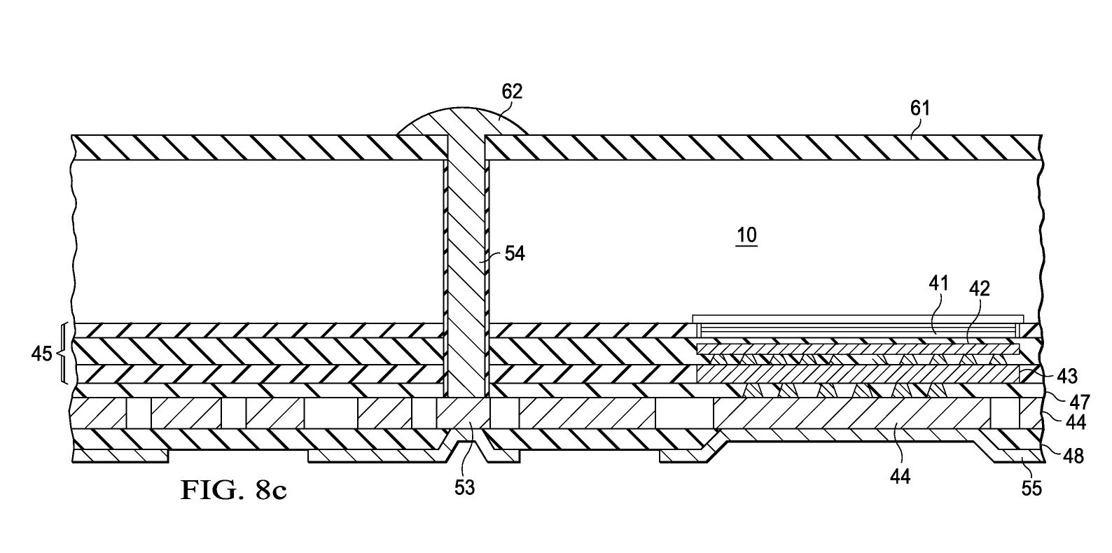

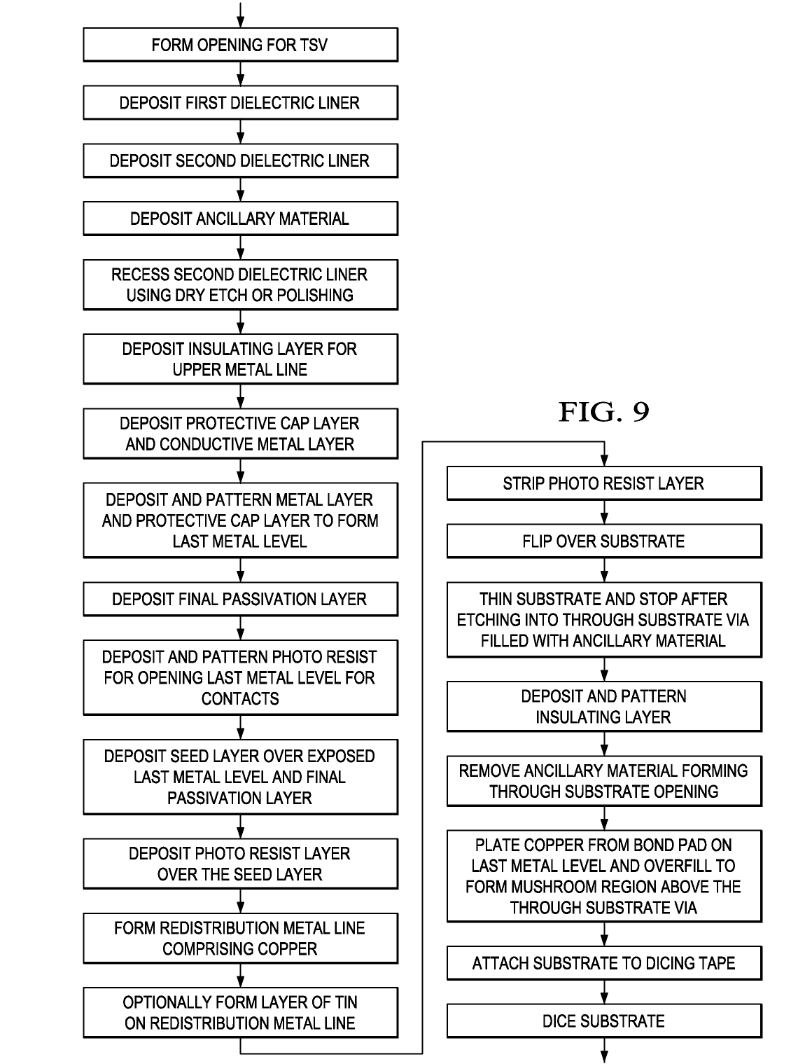

FIG. 8, along with the flow chart of FIG. 9, illustrates an embodiment of the invention describing steps during fabrication of a through substrate via.

As illustrated in FIG. 8a, the embodiment proceeds similar to the prior embodiment as described with respect to FIGS. 4a-4j. Unlike the prior embodiment, the conductive fill material 54 is plated to form a mushroom region above the substrate 10 (FIG. 8b). The mushroom region is formed after the through substrate opening 51 is filled up completely by continuing with an over-fill over the through substrate via.

In various embodiments, this process has a further advantage of improving process margin. For example, this embodiment enables filling through substrate vias of different widths or through substrate vias disposed in different regions across the wafer. For example, through substrate vias of different widths or through substrate vias disposed in different regions of the wafer exhibit different growth rates. The growth rate dependency may depend on a number of factors that may not be easily controlled, for example, pattern dependent density effects. Forming the overfill region (mushroom region) enables filling vias with slower growth rate by forming larger overfill regions over through substrate vias with faster growth rate. In various embodiments, the through substrate openings with larger growth rates will have larger overfill regions than through substrate openings with smaller growth rates. However, unlike typical processes, both types of through substrate vias are filled completely without forming defects, for example, voids within the substrate 10.

In various embodiments, this additional process latitude is utilized to trade-off design with yield. For example, thinner vias with increased surface area may be preferable for certain applications, for example, in RF components to increase the current carrying capacity of the vias relative to forming thicker vias. Similarly, thinner vias can be used in some regions to save real estate on the substrate 10 while using thicker vias in regions requiring capacity for higher current densities. These careful trade-offs are enabled by the use of embodiments of the process that advantageously improve 3D integration of semiconductor components.

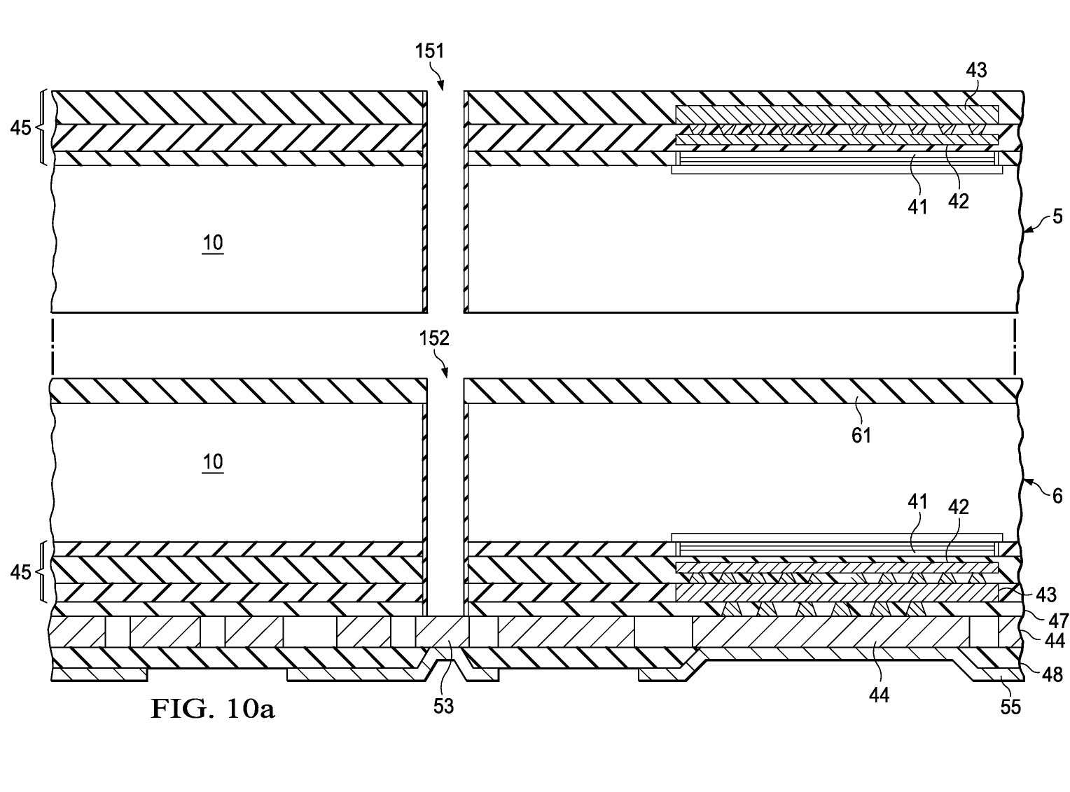

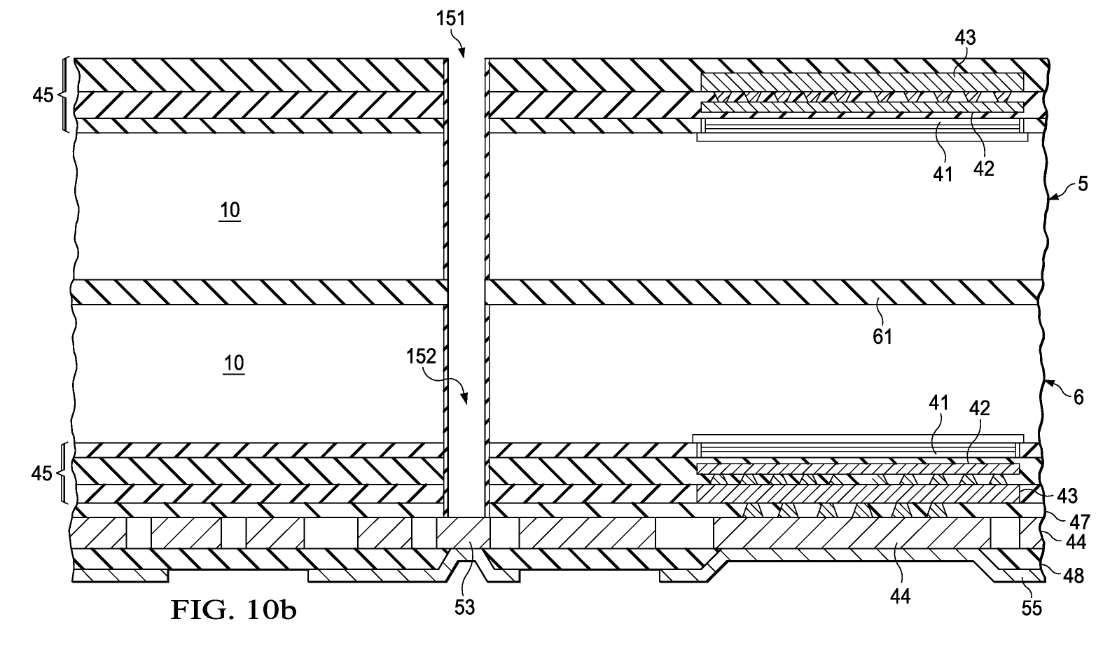

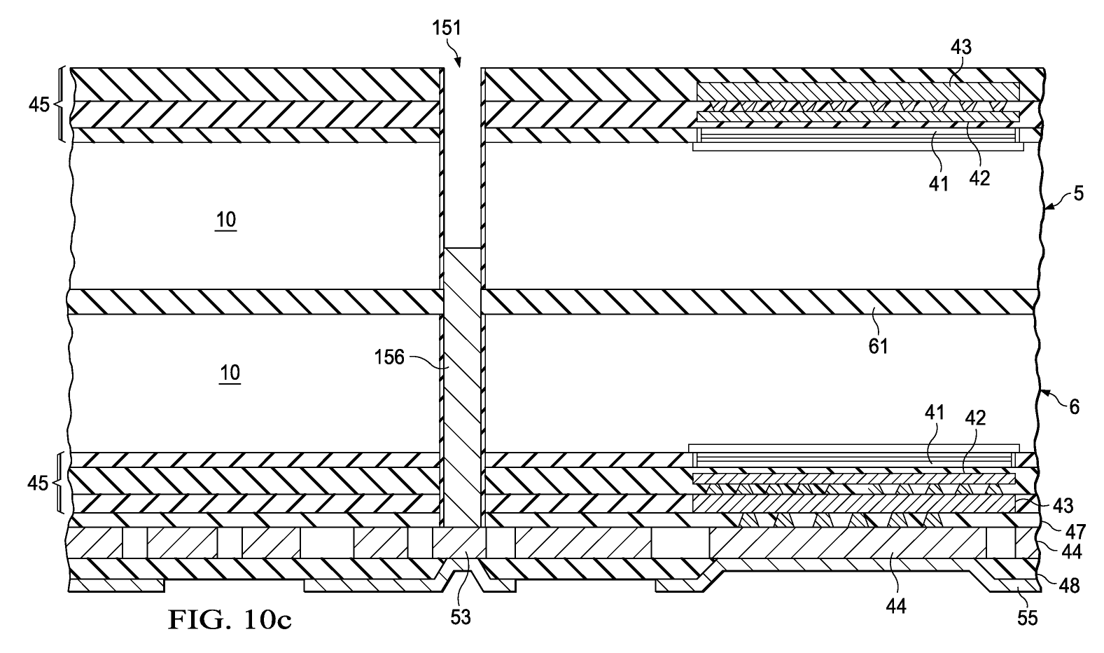

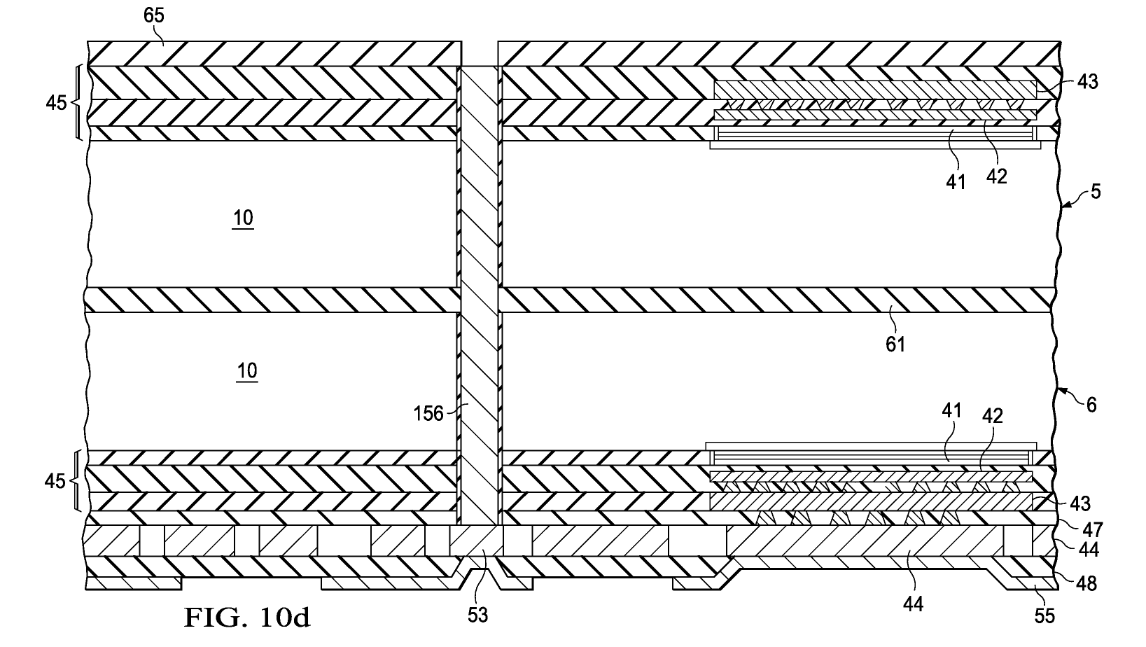

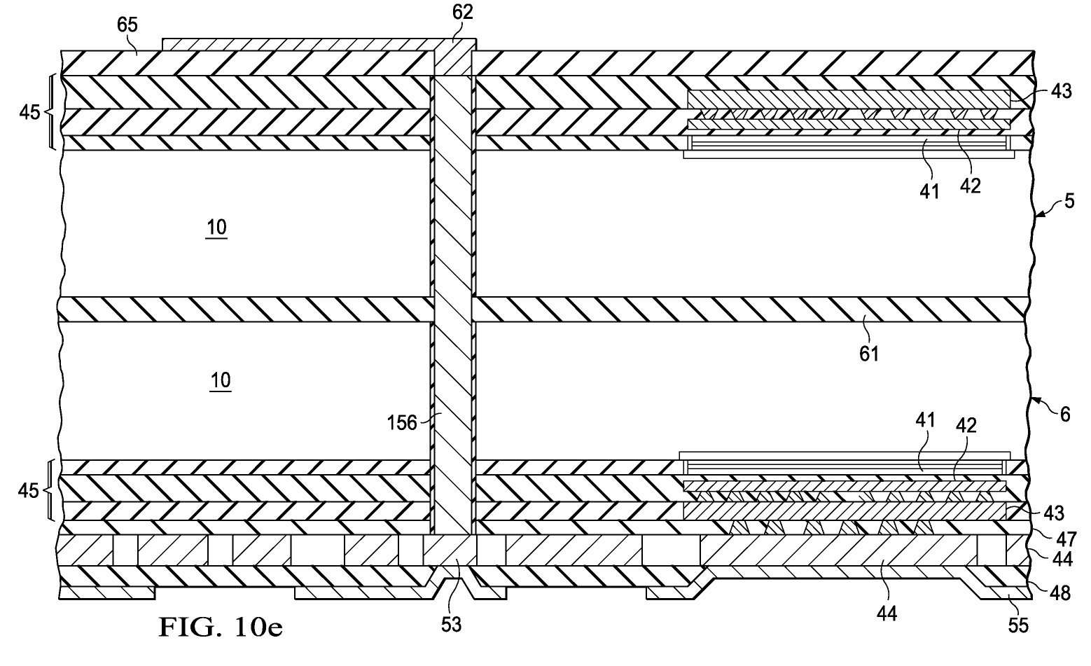

FIG. 10, which includes FIGS. 10a-10e, describes an embodiment of forming a stacked chip using embodiments of the invention.

FIG. 10 describes a wafer level process for fabricating a stacked chip. In this embodiment, multiple chips are fabricated separately on separate substrates. However, the stacked chip is formed on a wafer level using a single through substrate via formation step.

As illustrated in FIG. 10a, a first chip 5 on a first wafer and a second chip 6 on a second wafer are fabricated. The first chip 5 comprises a first through substrate opening 151 and the second chip 6 comprises a second through substrate opening 152. In one embodiment, the second chip 6 is processed for example as described in FIGS. 4a-4j. The first chip 5 is fabricated in a modified flow that includes skipping some of the process steps described in FIGS. 4a-4j. In particular, the steps forming the redistribution lines (as described in FIG. 4h) are skipped in forming the first chip 5.

The first and the second chips 5 and 6 are aligned together as illustrated in FIG. 10b such that the through substrate vias in each chip are aligned together. The first and the second through substrate vias 151 and 152 may be designed to facilitate good alignment. For example, in one embodiment, the first and the second through substrate vias 151 and 152 comprise different widths to allow misalignment errors. In various embodiments, the first and the second chips 5 and 6 are glued together after the alignment process, for example, by applying a suitable adhesive before placing the chips together. A curing process necessary to stabilize the adhesive may be performed.

Referring next to FIGS. 10c and 10d, a single electro-deposition step is used to form a single conductor 156 extending from the second chip 6 into the first chip 5. The electro plating is initiated from the front side bond pad 53 of the second chip 6 and proceeds through the second through substrate opening 152 into the first through substrate opening 151. Further, redistribution lines 65 are formed over the single conductor 156 (FIG. 10d). In various embodiments, use of a single electroplating process minimizes errors in misalignment and minimizes costs of stacking by reducing the number of fabrication steps involved in stacking chip.

Although the present invention and its advantages have been described in detail, it should be understood that various changes, substitutions and alterations can be made herein without departing from the spirit and scope of the invention as defined by the appended claims. For example, many of the features and functions discussed above can be implemented in software, hardware, or firmware, or a combination thereof. As another example, it will be readily understood by those skilled in the art that many of the features, functions, processes, and materials described herein may be varied while remaining within the scope of the present invention.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor chip comprising:
a first through substrate opening disposed in a substrate, the first through substrate opening comprising a first width, the first through substrate opening extending from a top surface of the substrate to a bottom surface of the substrate, the top surface comprising active devices, and the bottom surface being opposite to the top surface;
a dielectric liner disposed on sidewalls of the first through substrate opening; and
a conductive fill material filling the first through substrate opening, wherein the conductive fill material is disposed on the dielectric liner, the conductive fill material being disposed from a conductive bottom pad, the conductive bottom pad disposed over the top surface of the substrate.

2. The semiconductor chip of claim 1, wherein the conductive fill material comprises a single material and wherein the conductive fill material does not comprise an outer shell comprising a different conducting material than an inner core region.

3. The semiconductor chip of claim 1, wherein a conductive liner is not disposed between the conductive fill material and the dielectric liner.

4. The semiconductor chip of claim 1, wherein the sidewalls of the first through substrate opening comprise a surface roughness of about 5 nm to about 150 nm.

5. The semiconductor chip of claim 4, wherein the sidewalls of the first through substrate comprise protrusions and valleys of around 500 A.

6. The semiconductor chip of claim 1, wherein an aspect ratio of the first through substrate opening is between about 15 to about 150.

7. The semiconductor chip of claim 1, further comprising a second through substrate opening disposed in the substrate and extending from the top surface to the bottom surface, the second through substrate opening comprising a second width, wherein the second width is larger than the first width, wherein the dielectric liner is disposed on sidewalls of the second through substrate opening, and wherein the conductive fill material fills the second through substrate opening.

8. The semiconductor chip of claim 7, wherein the second width is at least 1.5 times the first width.

9. The semiconductor chip of claim 7, wherein an aspect ratio of the second through substrate opening is between about 15 to about 150.

10. The semiconductor chip of claim 1, wherein the conductive fill material comprises a material selected from the group consisting of nickel, gold, tin, silver, copper, aluminum, nickel molybdenum alloys, iron phosphide alloys, nickel phosphide alloys, and combinations thereof.

11. The semiconductor chip of claim 1, wherein the conductive fill material comprises copper.

12. A semiconductor chip comprising:
a top conductive pad disposed above a top surface of a substrate, the top surface comprising active devices;
a bottom conductive pad disposed adjacent a bottom surface of the substrate, the top surface being opposite the bottom surface;
a first vertical line disposed in the substrate, the first vertical line extending from the top conductive pad to the bottom conductive pad; and
a second vertical line disposed in the substrate, the second vertical line extending from the top conductive pad to the bottom conductive pad, wherein the first and the second vertical lines are electrically coupled in parallel between the top conductive pad and the bottom conductive pad.

13. The semiconductor chip of claim 12, wherein the first vertical line and the second vertical line are coupled through the top conductive pad and the bottom conductive pad.

14. The semiconductor chip of claim 12, wherein a width of the first vertical line and a width of the second vertical line are about the same.

15. The semiconductor chip of claim 12, wherein the first and the second vertical lines comprise copper.

16. A method of forming a semiconductor device comprising through substrate vias, the method comprising:
forming a first through substrate opening from a top surface of a substrate, the top surface comprising active devices; and
filling the through substrate opening from a bottom surface of the substrate using a one-dimensional deposition process, wherein the one-dimensional deposition process deposits from a bottom of the through substrate opening along a depth of the through substrate opening, wherein the bottom surface is opposite to the top surface, and wherein the bottom of the through substrate opening is adjacent the top surface.

17. The method of claim 16, wherein the deposition process comprises electrodeposition.

18. The method of claim 16, wherein the deposition process comprises electroless deposition.

19. The method of claim 16, wherein the bottom of the through substrate opening comprises a conductive material coupled to a potential node.

20. The method of claim 19, wherein sidewalls of the through substrate opening are insulated from the potential node.

21. A method of forming a semiconductor device comprising through substrate vias, the method comprising:
forming a first through substrate opening from a top surface of a substrate, the top surface comprising active devices;
filling the first through substrate opening with an ancillary material;
capping the first through substrate opening by forming a conductive capping layer over the ancillary material;
thinning the substrate from a back surface to expose a portion of the ancillary material, the back surface being opposite to the top surface;
after exposing the portion of the ancillary material, removing the ancillary material from the first through substrate opening to regenerate the first through substrate opening; and
forming a first conductor by filling a conductive material into the regenerated first through substrate opening.

22. The method of claim 21, wherein filling the conductive material comprises using a deposition process that adds conductive material starting from the conductive capping layer.

23. The method of claim 21, wherein filling the conductive material comprises electroplating using the conductive capping layer as a starting layer.

24. The method of claim 21, wherein filling the conductive material comprises precipitating the conductive material from an aqueous solution.

25. The method of claim 21, wherein the conductive material comprises a material selected from the group consisting of nickel, gold, tin, silver, copper, aluminum, nickel molybdenum alloys, iron phosphide alloys, nickel phosphide alloys, and combinations thereof.

26. The method of claim 21, further comprising:
forming a second through substrate opening from the top surface of the substrate, the second through substrate opening being parallel to the first through substrate opening;
filling the second through substrate opening with the ancillary material;
capping the second through substrate opening by forming the conductive capping layer over the ancillary material;
after exposing the portion of the ancillary material, removing the ancillary material from the second through substrate opening to regenerate the second through substrate opening; and
forming a second conductor by filling the conductive material into the regenerated second through substrate opening.

27. The method of claim 26, further comprising forming a conductive bond pad over the first and the second conductors.

28. A method of forming a semiconductor device comprising through substrate vias, the method comprising:
forming a first through substrate opening from a top surface of a substrate, the top surface comprising active devices;
forming a second through substrate opening from the top surface, the second through substrate opening comprising at least one dimension different from the first through substrate opening;
filling the first and the second through substrate openings with an ancillary material;
forming a conductive capping layer over the ancillary material;
thinning the substrate from a back surface to expose a portion of the ancillary material, the back surface being opposite to the top surface;
removing the ancillary material from the first and the second through substrate openings; and
filling a conductive material into the first and the second through substrate openings.

29. The method of claim 28, wherein a width of the second through substrate opening is larger than a width of the first through substrate opening.

30. The method of claim 29, wherein the width of the second through substrate opening is at least 1.5 times the width of the first through substrate opening.

31. The method of claim 28, wherein an aspect ratio of the second through substrate opening is larger than an aspect ratio of the first through substrate opening, wherein the aspect ratio is defined as a ratio of a width to a height.

32. The method of claim 31, wherein the aspect ratio of the second through substrate opening is at least twice the aspect ratio of the first through substrate opening.
